(19) United States
(12) Patent Application Publication
(10) Pub. No.: US 2025/0313480 A1
(43) Pub. Date: Oct. 9, 2025

(54) Solution-Processed Single Silicon Carbide Nanowires as Channel Layers in Transistors and Methods Thereof

(71) Applicants: UNM RAINFOREST INNOVATIONS, Albuquerque, NM (US); TRIAD NATIONAL SECURITY, LLC, Los Alamos, NM (US)

(72) Inventors: Sakineh CHABI, Albuquerque, NM (US); Jose CASTRO, Albuquerque, NM (US); Jinkyoung YOO, Los Alamos, NM (US)

(21) Appl. No.: 19/171,670

(22) Filed: Apr. 7, 2025

Related U.S. Application Data
(60) Provisional application No. 63/575,940, filed on Apr. 8, 2024.

(51) Int. Cl. C01B 32/984; B82Y 40/00; G03F 7/16; G03F 7/20; H01L 21/02; H10D 30/01; H10D 30/67

(52) U.S. Cl. CPC C01B 32/984; G03F 7/16; G03F 7/2059; H01L 21/02529; H01L 21/02628; H01L 21/02639; H10D 30/0316; H10D 30/6732; H10D 30/6737; H10D 30/6741; H10D 30/6757; B82Y 40/00; C01P 2004/16

(57) ABSTRACT

A method for fabricating single silicon carbide nanowires includes synthesizing silicon carbide using chemical vapor deposition; adding the silicone carbide to a solvent to form a suspension, sonicating the suspension, and separating a plurality of silicon carbide nanowires from the suspension after sonicating the suspension. Implementations of the method for fabricating single silicon carbide nanowires includes where synthesizing silicon carbide using chemical vapor deposition may include the introduction of silicon vapor, or adjusting a pH or maintaining a constant volume during the solution process. A bottom-gate transistor, or other integrated circuits may include layers having one or more of a plurality of silicon carbide nanowires positioned between the source and the drain.

### REFERENCE TO RELATED APPLICATIONS (PROVISIONAL)

This application claims the benefit of U.S. Provisional Patent Application No. 63/575,940, filed on Apr. 8, 2024, which is hereby incorporated by reference in its entirety.

### TECHNICAL FIELD

The present teachings relate generally to single silicon carbide nanowires and, more particularly, to silicon nanowires as channel layers for use in transistors.

### BACKGROUND

Silicon Carbide (SiC) semiconductor devices, including metal-oxide-semiconductor field-effect transistors (MOSFET) are increasingly being used in high power, high voltage, and high temperature applications because SiC has a larger bandgap, and much better thermal conductivity as compared to silicon. The use of SiC MOSFETs in battery applications, such as electric vehicles (EVs) can enable fast charging, since SiC can tolerate high voltage, high frequency operation when incorporated into semiconductor devices. Despite several advantages that SiC power devices have over silicon-based devices, they still have disadvantages. Current challenges with SiC MOSFETs include power loss due to the conduction loss, and material quality. These problems degrade the performance and reliability of the device and increase the overall cost. Additionally, while, the future of technology lies in scaling, and developing nano-scale level semiconductor devices, SiC devices remain in the micrometer range. Thus, as chips continue to shrink to improve efficiency, it is imperative to develop new SiC nanoscale devices to fully leverage the benefits of miniaturization.

Modern semiconductor devices need to be lightweight, ultrafast and highly efficient (with minimum power loss). These characteristics cannot be achieved with conventional semiconducting materials such as silicon. Bulk silicon carbide (SiC), by contrast, has many exceptional physical properties, including a wide band gap, high breakdown field, high strength, and high temperature tolerance. It is widely used in high-temperature, high-frequency, and high-power electronics, and as a wide band gap semiconducting material, silicon carbide has an edge over silicon. In addition, SiC benefits from high chemical and thermal stability and demonstrates an ability to resist radiation. These characteristics are critical for its application in extreme electronic environments. However, as a result of its quantum confinement, one dimensional (1D) SiC offers additional opportunities for applications compared to the corresponding bulk material. For instance, 1D SiC provides unusual physical properties, which are absent in other SiC configurations such as bulk SiC. Therefore, there is a need for devices incorporating 1D silicon carbide (SiC) such as nanowires and other configurations.

### SUMMARY

The following presents a simplified summary in order to provide a basic understanding of some aspects of one or more embodiments of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

A method for fabricating single silicon carbide nanowires is disclosed. The method for fabricating single silicon carbide nanowires includes synthesizing silicon carbide using chemical vapor deposition; adding the silicone carbide to a solvent to form a suspension, sonicating the suspension, and separating a plurality of silicon carbide nanowires from the suspension after sonicating the suspension. Implementations of the method for fabricating single silicon carbide nanowires includes where synthesizing silicon carbide using chemical vapor deposition may include the introduction of silicon vapor. The solvent can be selected from the group may include of a polar solvent, a non-polar solvent, or a combination thereof. The solvent can be a mixture of n-methyl-2-pyrrolidone and isopropyl alcohol. The suspension may include about 0.05 grams to about 2.0 grams of silicon carbide, and about 5 ml to about 20 ml of solvent. Sonicating the suspension is done for about 2 hours to about 4 hours. The method for fabricating single silicon carbide nanowires may include maintaining a constant volume of the suspension during sonicating by adding additional solvent to the suspension. The method for fabricating single silicon carbide nanowires may include adding the suspension after sonicating to a centrifuge tube, and operating a centrifuge may include the centrifuge tube with the suspension. The centrifuge can be operated at a speed of from about 1,000 rpm to about 13,000 rpm. The method for fabricating single silicon carbide nanowires may include separating the silicon carbide from the solvent using pipette collection. The method for fabricating single silicon carbide nanowires may include adjusting a pH of the suspension during fabrication of the silicon carbide nanowires. The method for fabricating single silicon carbide nanowires may include adjusting a pH of the suspension in a range from about 4 to about 9. A bottom-gate transistor, may include a substrate, a source deposited onto the substrate, a drain deposited onto the substrate in a location separated from the source, and one or more of a plurality of silicon carbide nanowires positioned between the source and the drain.

A method of fabricating an electronic device is disclosed, including providing a plurality of silicon carbide nanowires. The method of fabricating an electronic device includes depositing the plurality of silicon carbide nanowires onto a patterned substrate may include silicon. The method of fabricating an electronic device also includes where the plurality of silicon carbide nanowires are deposited using drop casting. Implementations of the method of fabricating an electronic device may include etching a surface of the substrate, and depositing a metal layer onto the surface of the substrate. The method of fabricating an electronic device may include applying a pattern on the substrate using e-beam lithography. The plurality of silicon carbide nanowires are deposited to form a layer of from about 0.25 nm to about 100 nm.

A bottom-gate transistor is disclosed, including a substrate that can include silicon dioxide. The transistor also includes a source disposed onto the substrate, a drain disposed onto the substrate. The transistor can include a patterning disposed on the substrate between the source and the drain. The transistor can include a plurality of silicon carbide nanowires positioned in the patterning. Implementations of the bottom-gate transistor can include where the source may include nickel and gold, and the drain may include nickel and gold. An integrated circuit may include the bottom-gate transistor.

The features, functions, and advantages that have been discussed can be achieved independently in various implementations or can be combined in yet other implementations further details of which can be seen with reference to the following description.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is flowchart illustrating a method for fabrication of silicon carbide nanowires, in accordance with the present disclosure.

FIG. 2 is an optical microscopy image of drop-casted SiC nanowires on silicon wafer, in accordance with the present disclosure.

FIG. 3 is an exemplary device, fabricated with a channel layer including silicon carbide nanowires, in accordance with the present disclosure.

FIGS. 4A and 4B depict an I-V data plot from a fabricated silicon carbide single nanowire device and a photograph of the silicon carbide single nanowire device using optical microscopy, in accordance with the present disclosure.

It should be noted that some details of the figures have been simplified and are drawn to facilitate understanding of the present teachings rather than to maintain strict structural accuracy, detail, and scale.

### DETAILED DESCRIPTION

Reference will now be made in detail to exemplary embodiments of the present teachings, examples of which are illustrated in the accompanying drawings. Wherever possible, the same reference numbers will be used throughout the drawings to refer to the same, similar, or like parts.

The present disclosure relates to electronic devices utilizing solution processed silicon carbide (SiC) single nanowires as channel layers. A bottom-gate transistor based on solution processed silicon carbide single nanowire (NW) was fabricated and characterized. In their basic configuration, SiC nanowire transistors consist of a source, a drain, and one or more SiC nanowire channels positioned between the source and the drain. The SiC NWs were dispersed onto a 100 nm thick SiO2/Si substrate by drop cast method. The fabricated device, which is yet to be optimized, demonstrates enhanced carrier mobility. The dispersed SiC nanowires can be prepared in various diameters and lengths.

Silicon Carbide (SiC) nanowires have several advantages over bulk SiC, primarily due to their characteristic nanoscale properties. At the nanoscale, SiC nanowires can have a greater degree of flexibility compared to bulk SiC. This flexibility can be advantageous in applications requiring bendable or stretchable materials, such as flexible electronics. The nanowire structure can help improve the efficiency of heat dissipation and the conduction of electrical signals, making them beneficial for use in electronics and thermal management systems. The use of these so called one dimensional (1D) SiC nanowires in metal oxide semiconductor field-effect transistors (MOSFET) will enable improved carrier mobility, substrate flexibility, reduced short-channel effects, and lack of dangling bonds. These features also further contribute positively to the overall performance and efficiency of the device. Owing to their nanoscale, the use of SiC nanowires (as compared to bulk SiC) enables more packed devices and the scaling down of the physical size of transistors.

Further, compared to bulk SiC which usually form a thick oxide layer (e.g. 200 nm SiO₂) readily, 1D SiC nanomaterial show excellent stability towards oxidation, which will positively affect their durability and performance. The thickness of SiC nanomaterials in the laboratory according to the present disclosure and described conditions ranges from 0.25 nm to 25 nm. In examples, SiC nanowire diameters can range from a few nanometer or less to about 1000 nm. The length can vary from a few micrometers or less to about a hundred micrometer or more. Additionally, bulk SiC suffers from poor crystalline structure, however 1D SiC has an ordered crystalline structure and this will positively affect materials reliability and performance. Thus, reduced geometry and structural flexibility, quantum confinement effects, improved crystalline structures and excellent environmental stability, and structural flexibility are expected to positively impact the power efficiency of the devices utilizing these 1D silicon carbide nanomaterials.

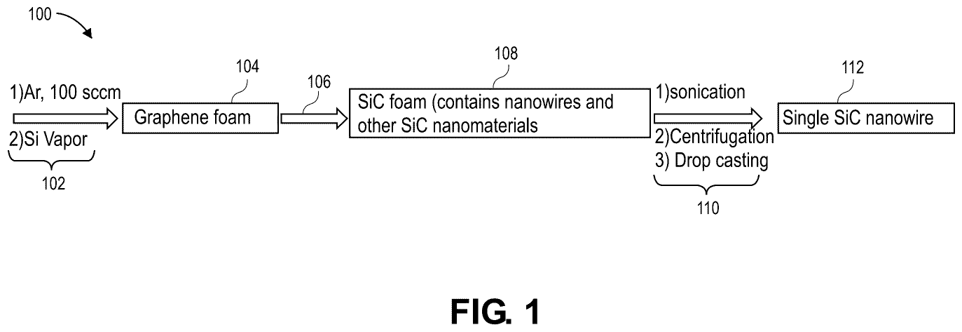

FIG. 1 is flowchart illustrating a method for fabrication of silicon carbide nanowires, in accordance with the present disclosure. In the schematic of the synthesis process 100, a chemical vapor deposition (CVD) process 102 was used to convert 106 graphene foam 104 to SiC foam 108. Then the CVD grown SiC foam 108 was crushed into powder. Under optical microscopy it was observed that SiC foam consists primarily of SiC nanowires. Single SiC nanowires 112 were isolated from the rest of the material using a multi-step solution processing method 110, which included sonication, centrifugation, and drop casting. The CVD grown material is in the form of powder or SiC foam, followed by the solution processing method, separation of single nanowires, dilution, transferring of silicon carbide nanowires to a substrate, for example, silicon dioxide or silicon carbide, followed by pipetting to drop cast one or more drops of the solution onto the substrates.

One-dimensional silicon carbide structures can be synthesized using a chemical vapor deposition (CVD) method, involving a reaction between carbon and silicon precursors. The resulting CVD-grown materials are then dispersed in a solution, suspension, or dispersion, followed by sonication and centrifugation to isolate single SiC nanowires from the batch. Next, the CVD grown SiC nanowires are diluted in a solvent, for example, N-methyl-2-pyrrolidone (NMP) or isopropyl alcohol (IPA), both purchased from Sigma Aldrich, with a ratio of 0.1 g in 15 ml solvent in a glass vial. The ratio of nanowires to solvent can be about 0.1 mg per 10 ml of solvent or greater. To start the solution process, the vials of SiC nanowires and solvent were sonicated for about 4 hours in a Branson 5800 Ultrasonic Cleaner, ensuring that to compensate for the water lost in the process due to the increased temperature by adding more to the water basin, keeping it at 1000 ml. In other examples, an Eppendorf sonication system could be used. This was followed by centrifugation using an Eppendorf Centrifuge 5425. For the centrifugation process, a sample of 2 ml was obtained from the 15 ml sample is collected via pipettes to a microtube. This was done at different speeds varying from 1,000 revolutions per minute (rpm) to 13,000 rpm for different samples, for varying times from about 5 to about 20 minutes.

It should be noted that in addition to NMP and IPA, methanol, other polar or non-polar organic solvents can also be used to chemically modify SiC. nanowire and physically separate single SiC nanowires from others in the methods of the present disclosure. NMP, and IPA were used in this experiment, due to the fact that some SiC nanowires were found to be coexisting with SiC nanosheets. Therefore, the use of NMP and IPA helped with separating SiC nanosheets from SiC nanowires, leading to single SiC nanowires for the purposes of the present fabrication methods and techniques. Alcohols, for example, isopropyl alcohol, or aqueous solvents can also be used. Examples include sodium hydroxide (NaOH), potassium hydroxide (KOH), or acidic based solutions having an average concentration of about 1M. Once the solvent is prepared. SiC powder precursor can be added to it. The initial concentration of SiC precursor in solvent can vary from about 0.5 mg/ml to about 5 g/ml or more. Various types of solution process can be used such as simple impregnation, for example, adding powder to solvent and then depositing it directly on to a substrate, sonication, centrifugation, or the combination of all.

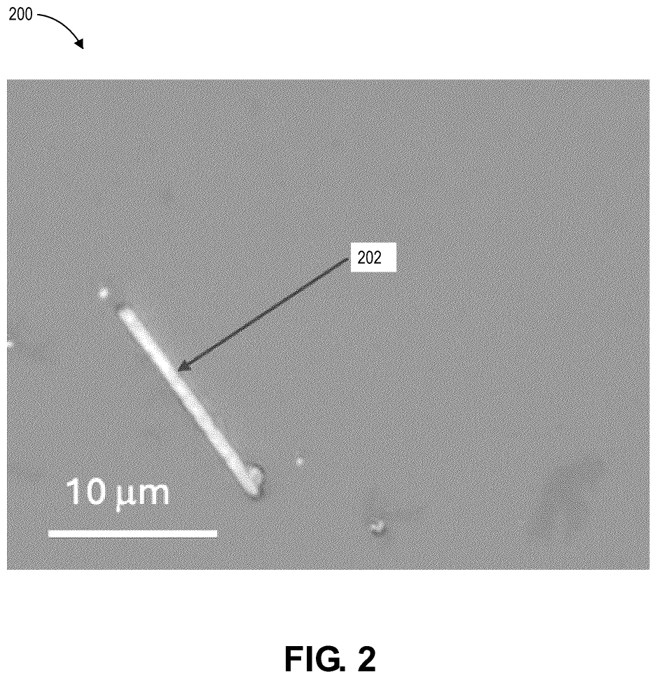

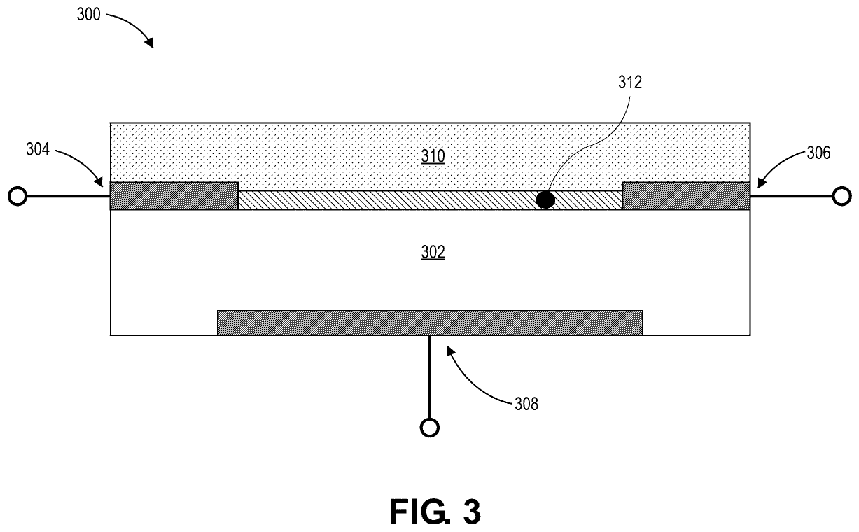

FIG. 2 is an optical microscopy image 200 of drop-casted SiC nanowires on silicon wafer, in accordance with the present disclosure. The single SiC nanowire 202 is shown with a 10 micron scale bar, indicating an approximate size of an example SiC nanowire 202. In other examples, the SiC nanowires can be in a size range of from about 10 nm to about 200 nm in diameter, and from about 20 micrometer to about 200 micrometer in length. It should further be noted that nanowire length can decrease during the solution process and centrifugation due to potential physical damage, but no change in the diameter would be expected. Generally speaking, nanowires retain their diameter (and length) during the solution processing step. This step is primarily used for separating single SiC nanowires and for chemical modification and doping of nanowires. FIG. 3 is an exemplary device, fabricated with a channel layer including silicon carbide nanowires, in accordance with the present disclosure. For an exemplary device 300 fabrication, SiO₂/Si can be used as substrate 302. The substrate 302, or insulator includes a bottom gate 308, disposed on a bottom surface of the substrate 302. A source 304 is disposed on a top surface of the substrate 302 and a drain 306 is disposed on a top surface of the substrate 302, with a conducting channel etched therebetween. In the device fabrication, micropipettes can be used to drop cast SiC nanowires from solution onto the substrate, in the conducting channel layer 312 that has been patterned onto the substrate, as described previously. In examples, an additional semiconductor layer is disposed on top of the source 304, drain, 306, and channel layer 312. The bottom-gate transistor based on silicon carbide (SiC) nanowire, as depicted schematically in FIG. 3, was fabricated and characterized. The SiC nanomaterials were dispersed and dispensed by dropcast method onto alignment marks-patterned 100 nm-thick silicon dioxide (SiO₂)/highly doped n-type silicon (Si) substrate. E-beam lithography followed, using a metallization process to fabricate the source/drain (S/D) electrodes. Prior to metal layer deposition on the defined S/D regions, a diluted hydrofluoric acid treatment was applied to remove the native oxide from the SiC nanostructure. The S/D electrodes consist of a bilayer of nickel (Ni, 130 nm) and gold (Au, 70 nm). FIG. 2 presents a typical optical microscopy image of the patterned SiC nanodevice after the lithography step, but before the metallization process.

In examples, various dopants can be added to the solution as well, such as N-type doping, using nitrogen (N) or phosphorus (P); P-type doping, using aluminum (Al) or boron (B). SiC nanowires can alternatively be prepared via different processes other than CVD, or annealing can be done after depositing SiC nanowires on substrates in order to improve crystallinity of the prepared materials.

The bottom-gate transistor of the present disclosure can include a substrate, a source deposited onto the substrate, a drain deposited onto the substrate in a location separated from the source, and one or more of a plurality of silicon carbide nanowires as fabricated according to the present methods, positioned between the source and the drain. The device can be fabricated by providing a plurality of silicon carbide nanowires, depositing the plurality of silicon carbide nanowires onto a patterned substrate comprising silicon, silicon dioxide, or other suitable semiconductor substrate materials, and wherein the plurality of silicon carbide nanowires are deposited using drop casting. In other examples, spin coating, dip coating, or spray coating can be used. Alternatively, the substrate can be immersed in the solution or brought into contact with the solution. In other examples, Also nanowires can be doped during the solution processing procedure or before or after that. In additional process steps associated with fabricating an electronic device, etching a surface of the substrate and depositing a metal layer onto the surface of the substrate to form the source and/or drain electrodes can be utilized. Further patterning for channel layers of semiconductor devices can accomplished using e-beam lithography or similar techniques known in the art of semiconductor fabrication. In examples, a plurality of silicon carbide nanowires are deposited to form a channel layer of from about 1 nm to about 100 nm in diameter and 10 micrometers to 1000 micrometer in length. In examples, the channel later is formed within a pattern disposed on the substrate between the source and the drain, connects the source electrode and the drain electrode, and incorporates a plurality of silicon carbide nanowires positioned in the patterning. Such bottom gate-transistors and other devices fabricated with the use of silicon carbide conductive layers, and in particular, silicon carbide nanowire conductive layers can be used as components in various integrated circuits.

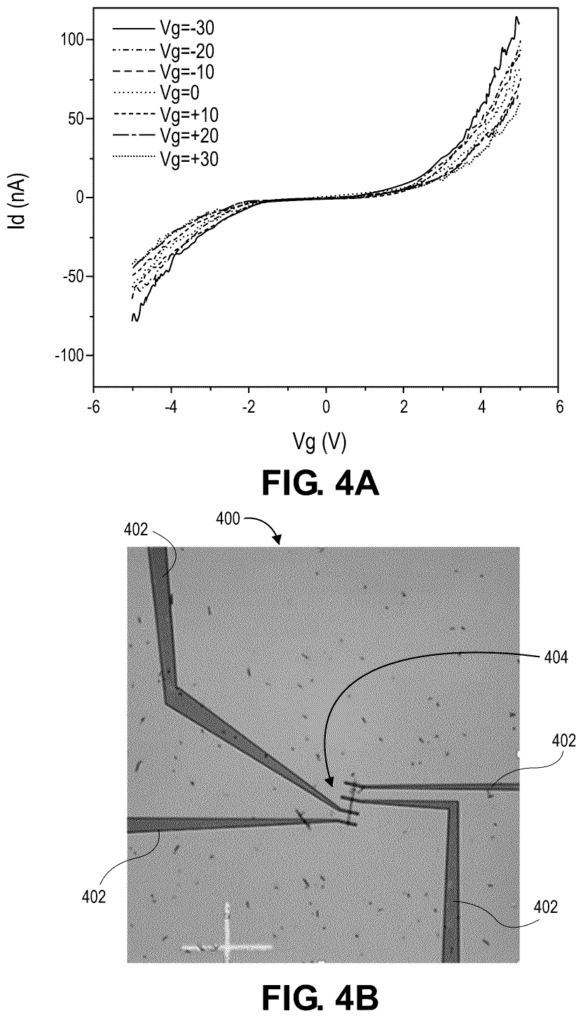

FIGS. 4A and 4B depict an I-V data plot from a fabricated silicon carbide single nanowire device and a photograph of the silicon carbide single nanowire device using optical microscopy, in accordance with the present disclosure. By measuring the drain current (ID) as a function of the gate voltage (VG) and using the transfer characteristics, the mobility can be calculated from the slope of the ID vs. VG curve. The estimated carrier mobility associated with the fabricated device varies from 1 cm²/Vs or less to 20 cm²/Vs or more, depending on the preparation process and doping. The improved electrical properties can be a direct results of the reduced dimensions of the silicon carbide nanowires and quantum confinement which leads to improvement of transport properties. The electrical properties, including carrier mobility, and doping type, and resistivity can be tuned by changing experimental parameters such as pH of solution during the solution process of fabrication. FIG. 4B shows an image 400 depicting a top view of a silicon carbide single nanowire device illustrating several electrodes 402 and a single silicon carbide nanowire 404 providing an electrical connection.

Advantages of the present disclosure include improved performance, a scaling advantage, flexibility and stretchability, and processibility. Applications of devices of the present disclosure include integrated circuits, sensing devices, utility in harsh environments, printed electronics, and fabrication of solution processable electronics. The solution process offers a solution in terms of separating single SiC nanowires from other materials, and also provides a simple facile approach for tuning the physical and chemical properties of nanowires. Solution processed SiC nanowire materials and processes provided by the present disclosure can further enable printable electronics, using a process that is easy, cost effective, and simple. The process can be used with or extended to other structures of silicon carbide such as SiC whiskers, nanotubes, nanosheets, and the like. Applications can further include low power electronics, where an entire chip can be immersed in another solution for preparing heterostructures or more complex structures

The fabricated nanowires are processed using a solution-based technique, which allows for the modification of their physical properties (e.g., electrical and optical characteristics). While transistor devices according to the present disclosure can be fabricated using single SiC nanowires, various architectures can be created by incorporating additional nanowires into the device (e.g., multi-nanowire, binanowire, or heteronanowire structures). These configurations enable gate-all-around structures, leading to more efficient SiC-based electronics.

While the present teachings have been illustrated with respect to one or more implementations, alterations and/or modifications may be made to the illustrated examples without departing from the spirit and scope of the appended claims. For example, it may be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or embodiments of the present teachings. It may be appreciated that structural objects and/or processing stages may be added, or existing structural objects and/or processing stages may be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items may be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. The terms “couple,” “coupled,” “connect,” “connection,” “connected,” “in connection with,” and “connecting” refer to “in direct connection with” or “in connection with via one or more intermediate elements or members.” Finally, the terms “exemplary” or “illustrative” indicate the description is used as an example, rather than implying that it is an ideal. Other embodiments of the present teachings may be apparent to those skilled in the art from consideration of the specification and practice of the disclosure herein. It is intended that the specification and examples be considered as exemplary only, with a true scope and spirit of the present teachings being indicated by the following claims.

What is claimed is:

1. A method for fabricating single silicon carbide nanowires, comprising:
synthesizing silicon carbide using chemical vapor deposition;
adding the silicone carbide to a solvent to form a suspension;
sonicating the suspension; and
separating a plurality of silicon carbide nanowires from the suspension after sonicating the suspension.

2. The method for fabricating single silicon carbide nanowires of claim 1, wherein synthesizing silicon carbide using chemical vapor deposition comprises the introduction of silicon vapor.

3. The method for fabricating single silicon carbide nanowires of claim 1, wherein the solvent is selected from the group consisting of a polar solvent, a non-polar solvent, or a combination thereof.

4. The method for fabricating single silicon carbide nanowires of claim 1, wherein the solvent is a mixture of N-methyl-2-pyrrolidone and isopropyl alcohol.

5. The method for fabricating single silicon carbide nanowires of claim 1, wherein the suspension comprises:
about 0.05 grams to about 2.0 grams of silicon carbide; and
about 5 mL to about 20 mL of solvent.

6. The method for fabricating single silicon carbide nanowires of claim 1, wherein sonicating the suspension is done for about 2 hours to about 4 hours.

7. The method for fabricating single silicon carbide nanowires of claim 1, further comprising maintaining a constant volume of the suspension during sonicating by adding additional solvent to the suspension.

8. The method for fabricating single silicon carbide nanowires of claim 1, further comprising:
adding the suspension after sonicating to a centrifuge tube; and
operating a centrifuge comprising the centrifuge tube with the suspension.

9. The method for fabricating single silicon carbide nanowires of claim 1, wherein the centrifuge is operated at a speed of from about 1,000 rpm to about 13,000 rpm.

10. The method for fabricating single silicon carbide nanowires of claim 1, further comprising separating the silicon carbide from the solvent using pipette collection.

11. The method for fabricating single silicon carbide nanowires of claim 1, further comprising adjusting a pH of the suspension during fabrication of the silicon carbide nanowires.

12. The method for fabricating single silicon carbide nanowires of claim 1, further comprising adjusting a pH of the suspension in a range from about 4 to about 9.

13. A bottom-gate transistor, comprising:
a substrate;
a source deposited onto the substrate;
a drain deposited onto the substrate in a location separated from the source; and
one or more of a plurality of silicon carbide nanowires of claim 1, positioned between the source and the drain.

14. A method of fabricating an electronic device, comprising:
providing a plurality of silicon carbide nanowires; and
depositing the plurality of silicon carbide nanowires onto a patterned substrate comprising silicon; and
wherein the plurality of silicon carbide nanowires are deposited using drop casting.

15. The method of fabricating an electronic device of claim 14, further comprising:
etching a surface of the substrate; and
depositing a metal layer onto the surface of the substrate.

16. The method of fabricating an electronic device of claim 14, further comprising applying a pattern on the substrate using e-beam lithography.

17. The method of fabricating an electronic device of claim 14, wherein the plurality of silicon carbide nanowires are deposited to form a layer of from about 0.25 nm to about 100 nm.

18. A bottom-gate transistor, comprising:
a substrate comprising silicon dioxide;
a source disposed onto the substrate;
a drain disposed onto the substrate; and
a patterning disposed on the substrate between the source and the drain; and
a plurality of silicon carbide nanowires positioned in the patterning.

19. The bottom-gate transistor of claim 18, wherein:
the source comprises nickel and gold; and
the drain comprises nickel and gold.

20. An integrated circuit, comprising the bottom-gate transistor of claim 19.
